(19) United States
(12) Patent Application Publication
(10) Pub. No.: US 2016/0276474 A1
(43) Pub. Date: Sep. 22, 2016

(54) SEMICONDUCTOR DEVICE

(71) Applicant: KABUSHIKI KAISHA TOSHIBA, Tokyo (JP)

(72) Inventor: Hiroshi Kono, Himeji Hyogo (JP)

(21) Appl. No.: 14/855,172

(22) Filed: Sep. 15, 2015

(30) Foreign Application Priority Data
Mar. 16, 2015 (JP) 2015-052278

(51) Int. Cl. H01L 29/78; H01L 23/528; H01L 27/092; H01L 29/16; H01L 29/06

(52) U.S. Cl. CPC H01L 29/7811; H01L 29/1608; H01L 29/0696; H01L 27/092; H01L 23/528; H01L 29/0615

(57) ABSTRACT

A semiconductor device according to an embodiment includes a first active region and a second active region. The first active region includes a n-type first source region at a first surface of the SiC substrate having the first surface and a second surface, a n-type first drain region, a first gate insulating film, a first gate electrode, a p-type second source region at the first surface and electrically connected to the first source region, a p-type second drain region, a second gate insulating film, and a second gate electrode electrically connected to the first gate electrode. The second active region includes a n-type first SiC region at the first surface and electrically connected to the second drain region, a p-type second SiC region, a n-type third SiC region, a third gate insulating film, and a third gate electrode electrically connected to the first source region and the second source region.

### CROSS-REFERENCE TO RELATED APPLICATION

This application is based upon and claims the benefit of priority from Japanese Patent Application No. 2015-052278, filed on Mar. 16, 2015, the entire contents of which are incorporated herein by reference.

### FIELD

Embodiments described herein relate generally to semiconductor devices.

### BACKGROUND

Silicon carbide (SiC) is expected as a material for a next-generation semiconductor device. The bandgap of SiC is three times wider than that of silicon (Si), the breakdown field strength thereof is about ten times higher than that of Si, and the thermal conductivity thereof is about three times higher than that of Si. The use of these characteristics makes it possible to achieve a semiconductor device which has low loss and can operate at a high temperature.

For example, a metal oxide semiconductor field effect transistor (MOSFET) using SiC can have low on-resistance and a high switching speed, as compared to a bipolar device using Si. Therefore, for example, the MOSFET has an excellent performance as a switching device of an inverter circuit.

When the value of dV/dt increases in the inverter circuit, the gate potential of an off-side switching device increases. This increase of gate potential induces a parasitic turn on of the switching device. There is a method which short-circuits the gate and the source using a Miller clamp circuit when the switching device is turned off and prevents an increase in gate potential, in order to prevent the parasitic turn on.

### BRIEF DESCRIPTION OF THE DRAWINGS

FIG. 1 is a layout diagram illustrating a semiconductor device according to an embodiment.

FIG. 2 is a circuit diagram illustrating the semiconductor device according to the embodiment.

FIG. 3 is a cross-sectional view schematically illustrating the semiconductor device according to the embodiment.

### DETAILED DESCRIPTION

A semiconductor device according to an embodiment includes a first active region and a second active region. The first active region includes: a n-type first source region provided at a first surface of a SiC substrate having the first surface and a second surface; a n-type first drain region provided at the first surface of the SiC substrate; a first gate insulating film provided on a portion of the first surface between the first source region and the first drain region; a first gate electrode provided on the first gate insulating film; a p-type second source region provided at the first surface of the SiC substrate and electrically connected to the first source region; a p-type second drain region provided at the first surface of the SiC substrate; a second gate insulating film provided on a portion of the first surface between the second source region and the second drain region; and a second gate electrode provided on the second gate insulating film and electrically connected to the first gate electrode. The second active region includes: a n-type first SiC region provided at the first surface of the SiC substrate and electrically connected to the second drain region; a p-type second SiC region provided between the first SiC region and the second surface; a n-type third SiC region provided between the second SiC region and the second surface; a third gate insulating film provided on the second SiC region; and a third gate electrode provided on the third gate insulating film and electrically connected to the first source region and the second source region.

Hereinafter, an embodiment of the invention will be described with reference to the drawings. In the following description, the same or similar members are denoted by the same reference numerals and the description thereof will not be repeated.

In the following description, n⁻, n, n⁻, p⁺, p, and p⁻ indicate the relative impurity concentration levels of each conductivity type. That is, n⁺ indicates that an n-type impurity concentration is high, as compared to n, and n⁻ indicates that an n-type impurity concentration is low, as compared to n. In addition, p⁺ indicates that a p-type impurity concentration is high, as compared to p, and p⁻ indicates that a p-type impurity concentration is low, as compared to p. In addition, in some cases, an n⁺ type and an n⁻ type are simply referred to as an n type and a p⁺ type and a p⁻ type are simply referred to as a p type.

Impurity concentration can be measured by, for example, secondary ion mass spectrometry (SIMS). In addition, the relative impurity concentration level can be determined from the carrier concentration level calculated by, for example, scanning capacitance microscopy (SCM).

In the specification, the concept of a “SiC substrate” includes, for example, a SiC layer which is formed on a substrate by epitaxial growth.

A semiconductor device according to this embodiment includes a cell region (second active region), a gate wiring region, and a Miller clamp circuit region (first active region) provided between the cell region and the gate wiring region. The Miller clamp circuit region includes a SiC substrate having a first surface and a second surface, a n-type first source region provided at the first surface of the SiC substrate, a n-type first drain region provided at the first surface of the SiC substrate, a first gate insulating film provided on a portion of the first surface between the first source region and the first drain region, a first gate electrode provided on the first gate insulating film, a p-type second source region that is provided at the first surface of the SiC substrate and is electrically connected to the first source region, a p-type second drain region provided at the first surface of the SiC substrate, a second gate insulating film provided on a portion of the first surface between the second source region and the second drain region, and a second gate electrode that is provided on the second gate insulating film and is electrically connected to the first gate electrode. The cell region includes a n-type first SiC region that is provided at the first surface of the SiC substrate and is electrically connected to the second drain region, a p-type second SiC region provided between the first SiC region and the second surface, a n-type third SiC region provided between the second SiC region and the second surface, a third gate insulating film provided on the second SiC region, and a third gate electrode that is provided on the third gate insulating film and is electrically connected to the first source region and the second source region.

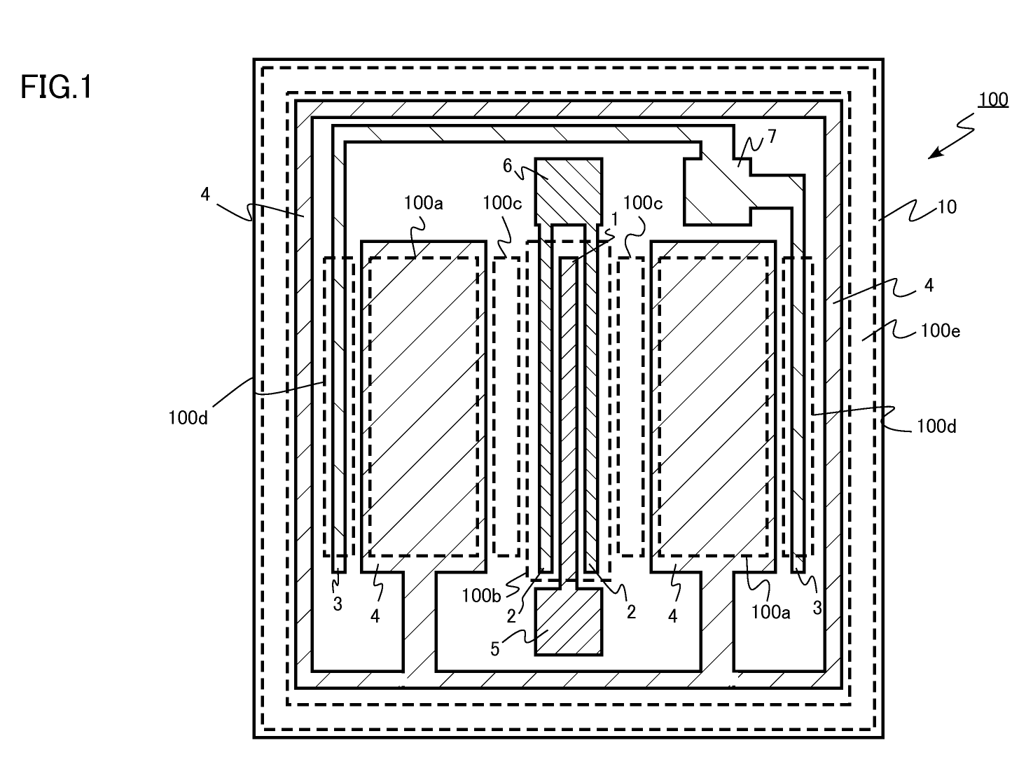

FIG. 1 is a layout diagram illustrating the semiconductor device according to this embodiment. The semiconductor device according to this embodiment is a vertical MOSFET using SiC.

FIG. 1 is a layout diagram illustrating a MOSFET 100 according to this embodiment, as viewed from the upper side. The MOSFET 100 is formed using a SiC substrate 10. The MOSFET 100 includes a cell region (second active region) 100a, a gate wiring region 100b, a Miller clamp circuit region (first active region) 100c, a reference wiring region 100d, and a termination region 100e.

In the cell region 100a, a plurality of cells of the vertical MOSFET are regularly arranged. The shape and arrangement of each cell are not particularly limited.

The gate wiring region 100b includes a gate signal wiring (first gate wiring) 1 through which a gate signal is propagated and a gate voltage wiring (second gate wiring) 2 through which a high-level gate voltage is propagated.

The Miller clamp circuit region 100c is provided between the cell region 100a and the gate wiring region 100b. In the Miller clamp circuit region 100c, a Miller clamp circuit is formed by an n-type MOSFET and a p-type MOSFET.

The cell region 100a is interposed between the reference wiring region 100d and the Miller clamp circuit region 100c. The reference wiring region 100d includes a reference wiring 3 used to receive the reference potential of a pulse generator in a gate driving circuit which is connected to the outside of the MOSFET 100.

A source electrode (first electrode) 4, a gate signal pad (second electrode) 5, a gate voltage pad (third electrode) 6, and a reference potential pad (fourth electrode) 7 are provided on the upper surface of the MOSFET 100. The source electrode (first electrode) 4, the gate signal pad (second electrode) 5, the gate voltage pad (third electrode) 6, and the reference potential pad (fourth electrode) 7 are provided on the SiC substrate 10. A drain electrode (fifth electrode) (not illustrated) is provided on the lower surface of the MOSFET 100.

A source voltage is applied to the source electrode 4. A gate signal is input to the gate signal pad 5. A high-level gate voltage is applied to the gate voltage pad 6. The reference potential of the pulse generator in the external gate driving circuit is output from the reference potential pad 7. A drain voltage is applied to the drain electrode.

The gate signal pad 5 is connected to the gate signal wiring 1. The gate voltage pad 6 is connected to the gate voltage wiring 2. The reference potential pad 7 is connected to the reference wiring 3.

The termination region 100e is provided in the outermost periphery of the SiC substrate 10. The source electrode 4 is provided along the inside of the termination region 100e.

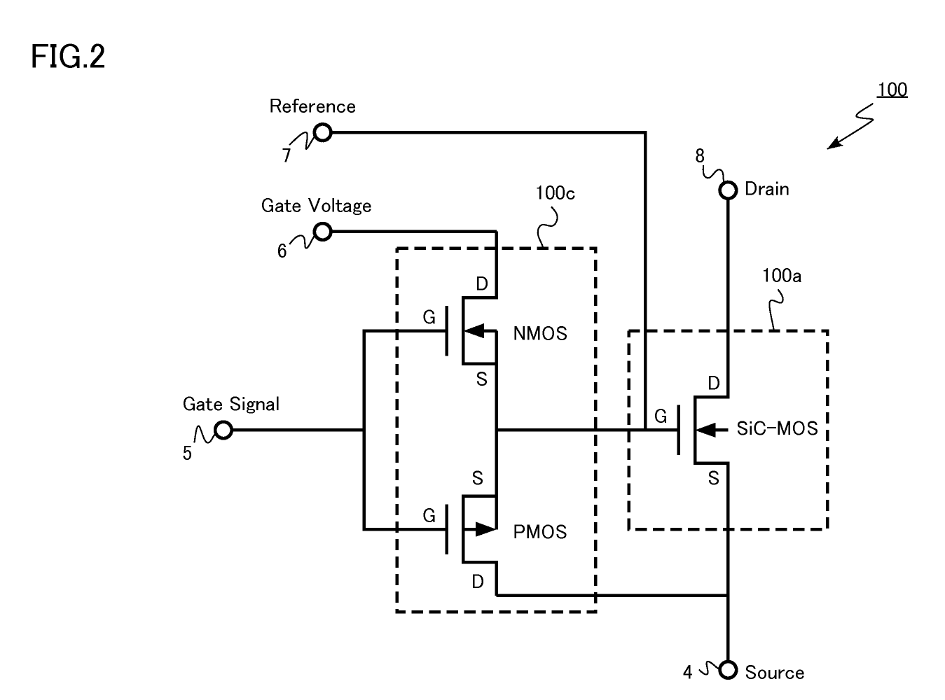

FIG. 2 is a circuit diagram illustrating the semiconductor device according to this embodiment. In the MOSFET 100, a vertical SiC MOSFET (hereinafter, referred to as a SiC-MOS), a p-type SiC MOSFET (hereinafter, referred to as a PMOS), and an n-type MOSFET (hereinafter, referred to as an NMOS) are formed on the same SiC substrate 10.

The SiC-MOS is formed in the cell region 100a. The PMOS and the NMOS are formed in the Miller clamp circuit region 100c.

The MOSFET 100 includes five terminals. The five terminals are the source electrode (Source: a first electrode) 4, the gate signal pad (Gate Signal: a second electrode) 5, the gate voltage pad (Gate Voltage: a third electrode) 6, the reference potential pad (Reference: a fourth electrode) 7, and a drain electrode (fifth electrode) 8. The source electrode 4, the gate signal pad 5, the gate voltage pad 6, the reference potential pad 7, and the drain electrode 8 are made of metal.

The PMOS and the NMOS are connected in series such that the sources thereof are connected to each other. The gate signal pad 5 is connected to the gates of the PMOS and the NMOS. The sources of the PMOS and the NMOS are connected to the gate of the SiC-MOS. The gate of the SiC-MOS is connected to the reference potential pad 7.

The drain of the PMOS and the source of the SiC-MOS are connected to the source electrode 4. The drain of the NMOS is connected to the gate voltage pad 6. The drain of the SiC-MOS is connected to the drain electrode 8.

When a high-level voltage is applied to the gate signal pad 5, the NMOS is turned on and the PMOS is turned off. A high-level gate voltage is input to the gate of the SiC-MOS and the SiC-MOS is turned on.

In contrast, when a low-level voltage is applied to the gate signal pad 5, the NMOS is turned off and the PMOS is turned on. The gate of the SiC-MOS is connected to the source through the PMOS and the SiC-MOS is turned off.

The gate potential of the gate of the SiC-MOS, which is the reference potential of the pulse generator, is output from the reference potential pad 7.

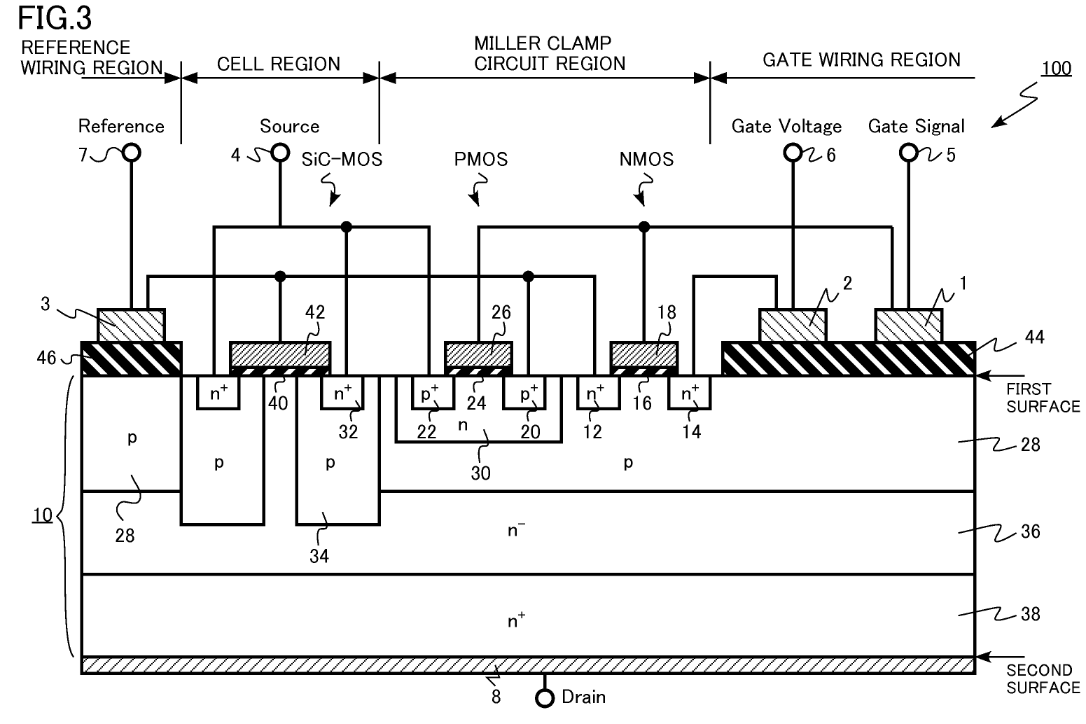

FIG. 3 is a cross-sectional view schematically illustrating the semiconductor device according to this embodiment.

The MOSFET 100 is formed using the SiC substrate 10. In the MOSFET 100, the cell region 100a, the gate wiring region 100b, the Miller clamp circuit region 100c, and the reference wiring region 100d are formed in the same SiC substrate 10.

The SiC substrate 10 has a first surface and a second surface. In FIG. 3, the first surface is an upper surface of the SiC substrate 10. In FIG. 3, the second surface is a lower surface of the SiC substrate 10.

In the MOSFET 100, the Miller clamp circuit region 100c includes a n-type first source region 12, a n-type first drain region 14, a first gate insulating film 16, a first gate electrode 18, a p-type second source region 20, a p-type second drain region 22, a second gate insulating film 24, a second gate electrode 26, a p-type first well region 28, and a n-type second well region 30.

In the MOSFET 100, the cell region includes an n⁺ source region (first SiC region) 32, a p-type base region (second SiC region) 34, an n⁻ drift region (third SiC region) 36, an n⁺ drain region (fourth SiC region) 38, a third gate insulating film. 40, and a third gate electrode 42.

A potential is applied to the p-type first well region 28 and the p-type base region 34 by an ohmic contact (not illustrated). The ohmic contact is provided on a p⁺ region (not illustrated). A potential is applied to the second n-type well region 30 by an ohmic contact (not illustrated). The ohmic contact is provided on an n⁺ region (not illustrated).

In the MOSFET 100, the gate wiring region 100b includes the gate signal wiring (first gate wiring) 1, the gate voltage wiring (second gate wiring) 2, and a field oxide film 44. The p-type first well region 28 is provided in the gate wiring region 100b.

In the MOSFET 100, the reference wiring region 100d includes the reference wiring 3 and a field oxide film 46. The p-type first well region 28 is provided in the reference wiring region 100d.

The MOSFET 100 includes the source electrode (Source: the first electrode) 4, the gate signal pad (Gate Signal: the second electrode) 5, the gate voltage pad (Gate Voltage: the third electrode) 6, and the reference potential pad (Reference: the fourth electrode) 7 which are provided on the first surface side. In addition, the MOSFET 100 includes the drain electrode (fifth electrode) 8 which comes into contact with the second surface.

The first source region 12 and the first drain region 14 are provided at the first surface. The first gate insulating film 16 is provided on a portion of the first surface between the first source region 12 and the first drain region 14. The first gate electrode 18 is provided on the first gate insulating film 16. The first source region 12, the first drain region 14, and the first gate electrode 18 are components of the NMOS.

The first gate insulating film 16 is provided on the first well region 28. The first well region 28 is provided between the first gate electrode 18 and the drift region 36. The first well region 28 is connected to the base region 34.

The second source region 20 and the second drain region 22 are provided at the first surface. The second gate insulating film 24 is provided on a portion of the first surface between the second source region 20 and the second drain region 22. The second gate electrode 26 is provided on the second gate insulating film 24. The second source region 20, the second drain region 22, and the second gate electrode 26 are components of the PMOS.

The second gate insulating film 24 is provided on the second well region 30. The second well region 30 is provided between the second gate electrode 26 and the first well region 28.

It is preferable that the depth of the base region 34 in the cell region be greater than the depth of the first well region 28 in order to prevent the latch-up of the Miller clamp circuit. The breakdown voltage of the cell region is reduced and latch-up is prevented. It is preferable that the following relationship be satisfied in order to prevent latch-up: the depth of the first well region 28 in the Miller clamp circuit region≦the depth of the first well region 28 in the gate wiring region≦the depth of the first well region 28 in the reference wiring region<the depth of the base region 34 in the cell region.

The second source region 20 is electrically connected to the first source region 12. The second gate electrode 26 is electrically connected to the first gate electrode 18.

The source region 32 is provided at the first surface. The base region 34 is provided between the source region 32 and the second surface. The drift region 36 is provided between the base region 34 and the second surface. The drain region 38 is provided at the second surface. The third gate insulating film 40 is provided on the base region 34. The third gate electrode 42 is provided on the third gate insulating film 40. The source region 32, the base region 34, the drift region 36, the drain region 38, the third gate insulating film 40, and the third gate electrode 42 are components of the SiC-MOS.

The source region 32 is electrically connected to the second drain region 22. The source region 32 and the second drain region 22 are connected to the source electrode 4. The third gate electrode 42 is electrically connected to the first source region 12 and the second source region 20.

The gate signal wiring 1 and the gate voltage wiring 2 are provided on the field oxide film 44. The gate signal wiring 1 and the gate voltage wiring 2 are made of, for example, metal.

The gate signal wiring 1 electrically connects the gate signal pad 5 to the first gate electrode 18 and the second gate electrode 26. The gate voltage wiring 2 electrically connects the gate voltage pad 6 to the first drain region 14.

The reference wiring 3 is provided on the field oxide film 46. The reference wiring 3 electrically connects the reference potential pad 7 to the third gate electrode 42.

A structure for electrically connecting the NMOS, the PMOS, the SiC-MOS, the gate signal wiring 1, the gate voltage wiring 2, and the reference wiring 3 is not illustrated. These components can be electrically connected to each other by a multi-layer wiring using an interlayer insulating film. For example, these components can be electrically connected to each other by a contact structure using metal or silicide, a metal wiring layer, a polysilicon wiring layer, and a silicide layer. For example, an oxide film or a film using a low-permittivity material can be used as the interlayer insulating film.

Next, the function and effect of this embodiment will be described.

For example, when the MOSFET is used as a switching device of an inverter circuit, in some cases, a device including a Miller clamp circuit is connected between a gate driving circuit and the MOSFET in order to prevent parasitic turn on. When the MOSFET is turned off, the Miller clamp circuit is used to short-circuit the gate and the source, thereby preventing parasitic turn on.

However, when the Miller clamp circuit is provided outside the MOSFET, for example, the short-circuit between the gate and the source is delayed by the influence of wiring resistance or wiring parasitic inductance between the MOSFET and the Miller clamp circuit and the wiring resistance or wiring parasitic inductance of the MOSFET, which makes it difficult to obtain a sufficiently high switching speed. In other words, it is difficult to increase the value of dV/dt in the inverter circuit. In particular, this problem is noticeable in a SiC device which can theoretically obtain a high switching speed in terms of material characteristics.

In the MOSFET 100 according to this embodiment, the Miller clamp circuit region 100c and the vertical MOSFET forming the cell region 100a are provided on the same SiC substrate 10. In addition, the Miller clamp circuit region 100c is provided between the cell region 100a and the gate wiring region 100b so as to be close to the cell. Therefore, a delay caused by the influence of the wiring resistance or wiring parasitic inductance between the MOSFET or the Miller clamp circuit and the wiring resistance or wiring parasitic inductance of the MOSFET is prevented. As a result, when the MOSFET is used as a switching device of an inverter circuit, the short circuit time between the gate and the source during the turn-off of the MOSFET is reduced. Therefore, it is possible to achieve the MOSFET 100 capable of preventing parasitic turn on.

In the above-described embodiment, the MOSFET is given as an example of the semiconductor device. However, the invention can also be applied to an insulated gate bipolar transistor (IGBT). When the invention is applied to the IGBT, as the structure of the device, the n⁺ drain region (fourth SiC region) 38 of the MOSFET 100 may be replaced with a p⁺ collector region.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a first active region; and
a second active region,
the first active region including:
a n-type first source region provided at a first surface of a SiC substrate having the first surface and a second surface;
a n-type first drain region provided at the first surface of the SiC substrate;
a first gate insulating film provided on a portion of the first surface between the first source region and the first drain region;
a first gate electrode provided on the first gate insulating film;
a p-type second source region provided at the first surface of the SiC substrate and electrically connected to the first source region;
a p-type second drain region provided at the first surface of the SiC substrate;
a second gate insulating film provided on a portion of the first surface between the second source region and the second drain region; and
a second gate electrode provided on the second gate insulating film and electrically connected to the first gate electrode, and
the second active region including:
a n-type first SiC region provided at the first surface of the SiC substrate and electrically connected to the second drain region;
a p-type second SiC region provided between the first SiC region and the second surface;
a n-type third SiC region provided between the second SiC region and the second surface;
a third gate insulating film provided on the second SiC region; and
a third gate electrode provided on the third gate insulating film and electrically connected to the first source region and the second source region.

2. The device according to claim 1, further comprising:
a first electrode provided above the first surface and electrically connected to the second drain region and the first SiC region;
a second electrode provided above the first surface and electrically connected to the first gate electrode and the second gate electrode;
a third electrode provided above the first surface and electrically connected to the first drain region;
a fourth electrode provided above the first surface and connected to the third gate electrode; and
a fifth electrode provided at the second surface.

3. The device according to claim 2, further comprising:
a gate wiring region,
wherein the first active region is provided between the second active region and the gate wiring region.

4. The device according to claim 3, further comprising:
a first gate electrode wiring provided in the gate wiring region and electrically connecting the second electrode to the first gate electrode and the second gate electrode; and
a second gate electrode wiring provided in the gate wiring region and electrically connecting the third electrode to the first drain region.

5. The device according to claim 1, further comprising:
a p-type first well region provided between the first gate electrode and the third SiC region and connected to the second SiC region.

6. The device according to claim 5, further comprising:
an n-type second well region provided between the second gate electrode and the first well region.

7. The device according to claim 1, further comprising:
a fourth SiC region provided at the second surface of the SiC substrate and having a higher n-type impurity concentration than the third SiC region.

8. The device according to claim 5,
wherein the second SiC region is deeper than the first well region.

9. The device according to claim 4,
wherein an oxide film is provided between the first surface and the first gate electrode wiring and between the first surface and the second gate electrode wiring.

10. The device according to claim 3, further comprising:
a termination region surrounding the first active region, the second active region, and the gate wiring region.
